(19) United States
(12) Patent Application Publication
(10) Pub. No.: US 2020/0198481 A1
(43) Pub. Date: Jun. 25, 2020

(54) WIRELESS POWER TUNING NETWORK

(71) Applicant: Lear Corporation, Southfield, MI (US)

(72) Inventors: David A. Hein, Sterling Heights, MI (US); Lorenzo Scales, Southfield, MI (US)

(21) Appl. No.: 16/709,561

(22) Filed: Dec. 10, 2019

Related U.S. Application Data
(60) Provisional application No. 62/784,204, filed on Dec. 21, 2018.

(51) Int. Cl. B60L 53/12; H02J 50/12; H03H 7/40; B60L 53/53

(52) U.S. Cl. CPC B60L 53/12; B60L 53/53; H03H 7/40; H02J 50/12

(57) ABSTRACT

A system for a charging a vehicle is provided. The system includes a power generating device and one or more controllers. The power generating device is configured to generate a first energy signal corresponding to a requested amount of voltage for one of a vehicle and a base pad during a vehicle charging operation. The controller is configured to receive a request indicative of the requested amount of voltage to provide to the vehicle during the vehicle charging operation and to control the power generating device to generate the first energy signal based on the request. The controller is further configured to determine a resonant frequency of the first energy signal and to adjust a capacitance of a tuning capacitor network based on the determined resonant frequency to compensate for a distance variation between a vehicle pad and the base pad during the vehicle charging operation.

This application claims the benefit of U.S. provisional Application No. 62/784,204 filed on Dec. 21, 2018, the disclosure of which is incorporated in its entirety by reference herein.

### TECHNICAL FIELD

Aspects disclosed herein generally relate to a wireless power tuning network. Specifically, aspects disclosed herein may relate to a wireless power tuning network as utilized in connection with charging a vehicle. These aspects and other will be discussed in more detail herein.

### BACKGROUND

U.S. Pat. No. 8,957,549 to Kesler et al. provides a mobile wireless receiver for use with a first electromagnetic resonator coupled to a power supply. A load associated with an electrically powered system that is disposed interior to a vehicle, and a second electromagnetic resonator configured to be coupled to the load and moveable relative to the first electromagnetic resonator. The second electromagnetic resonator is configured to be wirelessly coupled to the first electromagnetic resonator to provide resonant, non-radiative wireless power to the second electromagnetic resonator from the first electromagnetic resonator. The second electromagnetic resonator is configured to be tunable during system operation so as to at least one of tune the power provided to the second electromagnetic resonator and tune the power delivered to the load.

### SUMMARY

In at least one embodiment, a system for a charging a vehicle is provided. The system includes a power generating device and one or more controllers. The power generating device is configured to generate a first energy signal corresponding to a requested amount of voltage for one of a vehicle and a base pad during a vehicle charging operation. The one or more controllers is configured to receive a request indicative of the requested amount of voltage to provide to the vehicle during the vehicle charging operation and to control the power generating device to generate the first energy signal based on the request. The one or more controllers is further configured to determine a resonant frequency of the first energy signal and to adjust a capacitance of a tuning capacitor network based on the determined resonant frequency to compensate for a distance variation between a vehicle pad and the base pad during the vehicle charging operation.

In at least another embodiment, a system for a charging a vehicle is provided. The system includes a vehicle pad, a base pad, a wall box unit, and one or more controllers. The vehicle pad is positioned on a vehicle. The base pad is positioned below the vehicle pad for inductively transmitting a voltage signal to the vehicle pad during a vehicle charging operation. The wall box unit is positioned in a building to facilitate the vehicle charging operation between the vehicle pad and the base pad. The wall box unit includes a power generating device configured to generate a first energy signal corresponding to a requested amount of voltage for use by the base pad to inductively transmit the voltage signal to the vehicle pad. The one or more controllers are configured to receive a request from the vehicle indicative of the requested amount of voltage to provide to the vehicle during the vehicle charging operation and to control the power generating device to generate the first energy signal based on the request. The one or more controllers are further configured to determine a resonant frequency of the first energy signal and to adjust a capacitance of a tuning capacitor network based on the determined resonant frequency to compensate for a variation between the base pad and the vehicle pad during the vehicle charging operation.

In at least another embodiment, a method for a charging a vehicle is provided. The method includes generating, via a power generating device, a first energy signal corresponding to a requested amount of voltage for one of a vehicle and a base pad during a vehicle charging operation and receiving a request from the vehicle indicative of the requested amount of voltage to provide to the vehicle during the vehicle charging operation. The method further includes controlling the power generating device to generate the first energy signal based on the request and determining a resonant frequency of the first energy signal. The method further includes adjusting a capacitance of a tuning capacitor network based on the determined resonant frequency to compensate for a distance variation between the vehicle and the base pad during the vehicle charging operation.

### BRIEF DESCRIPTION OF THE DRAWINGS

The embodiments of the present disclosure are pointed out with particularity in the appended claims. However, other features of the various embodiments will become more apparent and will be best understood by referring to the following detailed description in conjunction with the accompanying drawings in which:

FIG. 1 an example of a system that implements provides a wireless tuning network in accordance to one embodiment;

FIG. 2 corresponds to one example of a plot of a direct current (DC) bias characteristic in connection with at least a portion of the wireless tuning network in accordance to one embodiment;

FIGS. 3A-3B depict a more detailed view of a wall box unit 16 in accordance to one embodiment.

FIG. 4 generally depicts a more detailed implementation of a tuning capacitor network in accordance to one embodiment; and

FIG. 5 generally depicts one example of a method for performing a variable wireless tuning network in accordance to one embodiment.

### DETAILED DESCRIPTION

As required, detailed embodiments of the present invention are disclosed herein; however, it is to be understood that the disclosed embodiments are merely exemplary of the invention that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present invention.

The embodiments of the present disclosure generally provide for a plurality of circuits or other electrical devices. All references to the circuits and other electrical devices and the functionality provided by each are not intended to be limited to encompassing only what is illustrated and described herein. While particular labels may be assigned to the various circuits or other electrical devices disclosed, such labels are not intended to limit the scope of operation for the circuits and the other electrical devices. Such circuits and other electrical devices may be combined with each other and/or separated in any manner based on the particular type of electrical implementation that is desired. It is recognized that any circuit or other electrical device disclosed herein may include any number of microcontrollers, a graphics processor unit (GPU), integrated circuits, memory devices (e.g., FLASH, random access memory (RAM), read only memory (ROM), electrically programmable read only memory (EPROM), electrically erasable programmable read only memory (EEPROM), or other suitable variants thereof), and software which co-act with one another to perform operation(s) disclosed herein. In addition, any one or more of the electrical devices may be configured to execute a computer-program that is embodied in a non-transitory computer readable medium programmed to perform any number of the functions as disclosed herein and/or in the figures.

Tuning systems for wireless chargers may be known in the art. These systems generally include a vehicle pad positioned on a vehicle to be placed over a base pad that is positioned on a ground (or floor). In general, the vehicle pad and the base pad may be magnetically (or inductively) coupled such that the base pad transfers energy to the vehicle pad. The vehicle pad transfers the power from the base pad to the vehicle for purposes of charging one or more batteries in the vehicle. The vehicle pad is generally required to be positioned within a specified tolerance zone with respect to the base pad to ensure adequate inductive coupling between the vehicle pad and the base pad. The inductive coupling between the vehicle pad and the base pad changes based on different alignment positions between the vehicle pad and the base pad during the charging operation. The inductive coupling may also change based on the relative height of the vehicle relative to the base pad, which is located on the ground; the relative height may vary based on, for instance, a variable-height suspension being employed in the vehicle. The efficiency of the power transfer between the vehicle pad and the base pad may be based on a tuning of the wireless power transfer system. Generally, when a fixed tuning capacitor is used, the efficiency may be significantly affected by the alignment between the vehicle pad and base pad. For a good alignment and fixed tuning, the efficiency may be 92% or greater, but for other alignment positions, the efficiency may drop below for example 85% and 92%. With the fixed tuning capacitor, the system may not able to compensate for the impacts of different vehicle alignment positions or adapt the tuning. A variable tuning capacitor as now disclosed herein may be used to improve the efficiency to, for example, greater than 90% under all conditions which may provide a significant improvement in energy transfer.

Various prior art approaches may include a matching network that utilizes switching capacitors to adjust the tuning of the system. For example, these systems merely switch capacitors in an out for purposes of tuning which may be very expensive. These systems also require a high frequency drive of the switched capacitors and complex electronics to reduce losses in the switch capacitor network.

In light of the foregoing, aspects disclosed herein generally provide, inter alia, an improved wireless power transfer efficiency, reduced total cost of the electronics to implement the technology, and the ability to adjust a tuning point of the wireless power transfer system.

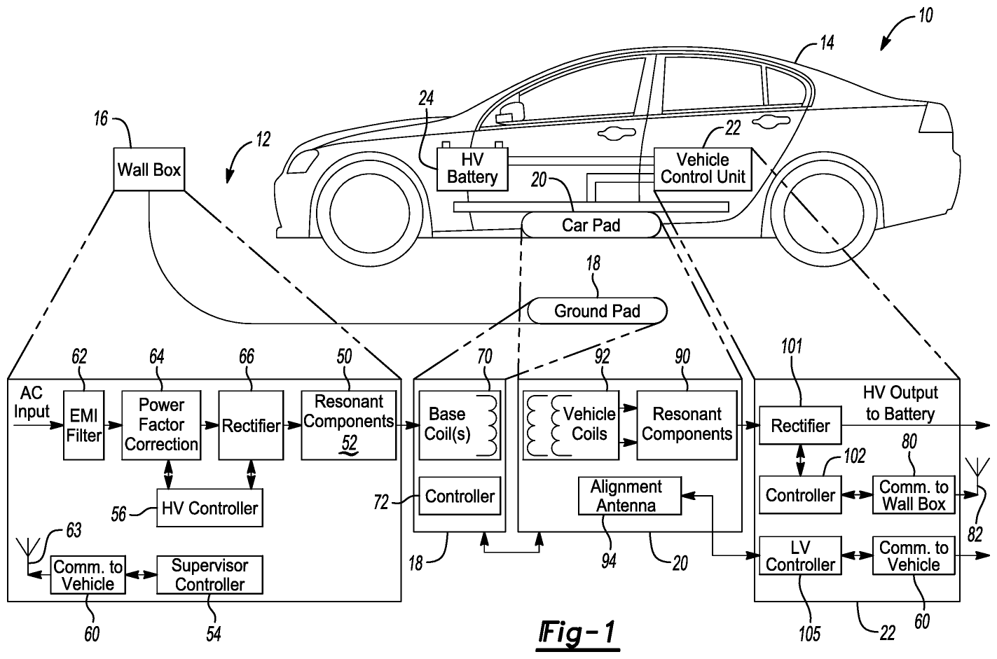

FIG. 1 depicts an example of a system 10 that provides a wireless tuning network 12 for a vehicle 14 in accordance to one embodiment. The system 10 generally includes a wall box unit 16 (or power generating device), a ground pad (or base pad) 18, a vehicle (or car) pad 20, and a vehicle control unit 22. In general, the wall box unit 16 is configured to receive an AC input and provide a AC based voltage to the base pad 18. The wall box unit 16 may be mounted or positioned about a building or dwelling for providing the AC based voltage to the base pad 18. In another example, the wall box unit 16 may be arranged as a portable unit that connects to an outlet of the building or dwelling (not shown) to provide the AC based voltage to the base pad 18. The base pad 18 may be inductively coupled to the vehicle pad 20 and transfer energy (e.g., AC magnetic field) to the vehicle pad 20 when the vehicle pad 20 is aligned over the base pad 18.

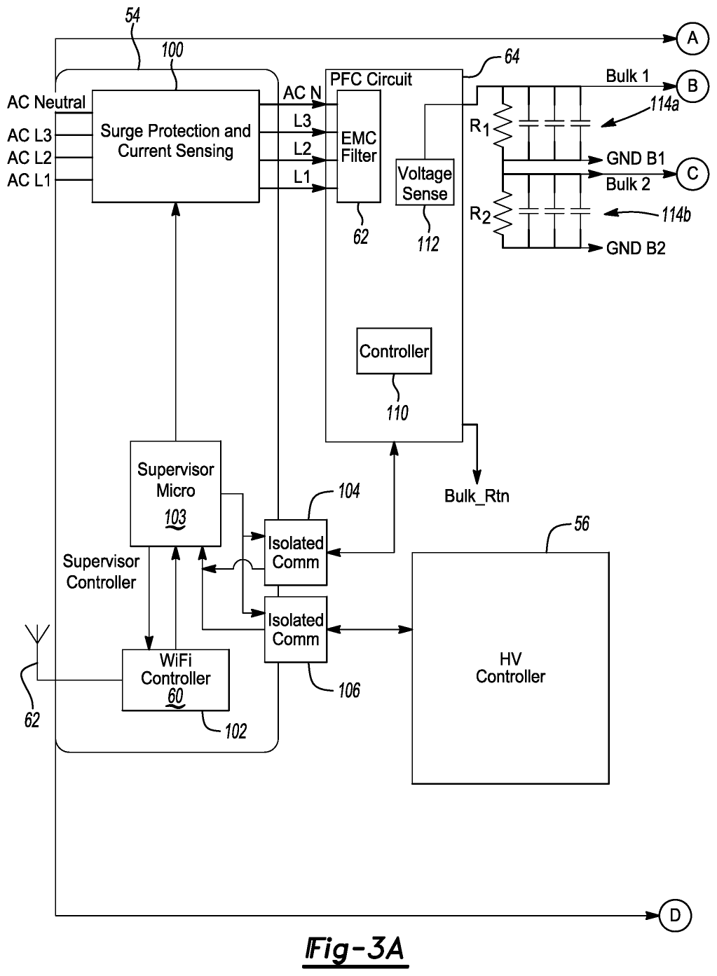

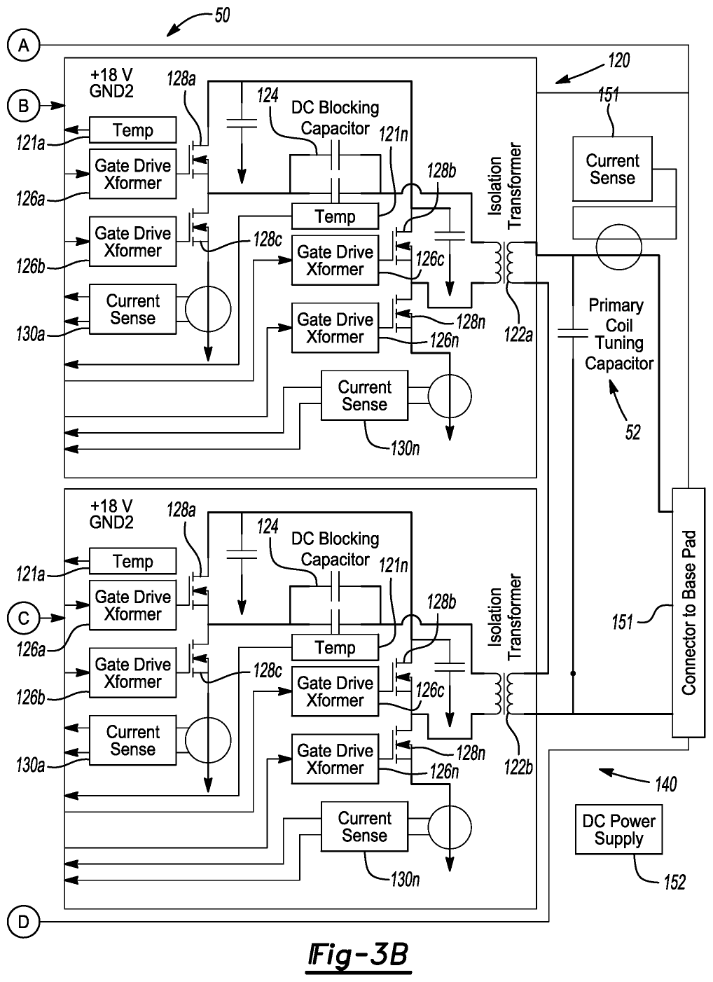

The vehicle pad 20 may rectify the transferred energy and transmit the rectified energy to the vehicle control unit 22. The vehicle control unit 22 receives the AC based output from the vehicle pad 20 and generates a DC based voltage (e.g., 400V or other suitable value). The vehicle control unit 22 then transfers the DC based voltage to one or more batteries 24 in the vehicle 14. The wall box unit 16 may include, resonant component circuitry 50 (e.g., inductor(s), capacitor(s) and one or more inverters) that provide the AC energy to a base coil(s) 70 positioned within the base pad 18. This will be explained in more detail in connection with FIGS. 3A-3B. The resonant component circuitry 50 may include a tuning capacitor network 52 that interacts with the base coil 70 positioned within the base pad 18. The tuning capacitor network 52 interacts with the base pad 18 to tune the same to enable wireless charging.

The wall box unit 16 generally includes a supervisor controller 54, a high voltage (HV) controller 56, and a vehicle communication network 60. The vehicle communication network 60 may be part of the supervisor controller 54 or the HV controller 56. In general, the vehicle 14 and the wall box unit 16 may engage in bi-directional communication with one another. In one example, the vehicle 14 may indicate the amount of AC power to provide to the base pad 18 and the amount of time to provide such power via the vehicle communication network 60 while the vehicle 14 is undergoing a vehicle charging operation. The vehicle 14 and the wall box unit 16 may engage in wireless communication via a transceiver 63. The vehicle control unit 22 may also include a communication network 80 and a transceiver 82 for communicating such information to the wall box unit 16.

The wall box unit 16 further includes a filter 62, power factor correction (PFC) circuit 64. The filter 62 filters the incoming AC signal and provides the filtered AC signal to the PFC circuit 64. The PFC circuit 64 may increase a power factor of the filtered incoming AC signal to generate an increased incoming AC signal. The PFC circuit 64 in turn rectifies the increased incoming AC signal into a DC signal which is then provided to the resonant component circuitry 50. The inverter of the resonant component circuitry 50 inverts the DC signal into an AC output (or AC energy) which is then fed to the base plate 18.

In general, the resonant component circuitry 50 provides the AC energy at a resonant frequency for delivery to the base pad 18. The resonant frequency of the transmitted AC energy varies based on the overall difference in length (or height) between the vehicle pad 20 and the base pad 18. For example, in the event a distance between the vehicle pad 20 and the base pad 18 is below a predetermined length (or distance), the inductance of the AC energy decreases and it may be necessary to increase the capacitance to adjust for the decrease in inductance (e.g., the resonant frequency is defined by Fr=½*π*√(L*C)). In this situation, sheet metal belonging to the vehicle 14 may be positioned closer to the base pad 20 which may cause the base coil 70 inductance to be reduced. Thus, a DC power supply (now shown) within the wall box unit 16 may decrease the amount of DC voltage provided to the tuning capacitor network 52 to increase the capacitance on the AC energy provided to the base pad 18 to thereby keep the resonant frequency the same. In the event the distance between the base pad 18 and the vehicle 14 is greater than the predetermined length), then the resonant frequency of the AC energy generated by the wall box unit 16 reduces as the inductance increases. Thus, the DC power supply may then increase the amount of DC voltage provided to the tuning capacitor network 52 to decrease the capacitance on the AC energy provided to the base pad coil 90. As can be seen, the tuning capacitor network 52 is variable based on the DC voltage provided by the DC power supply. Any number of the capacitors that form the tuning capacitor network 52 may be implemented as ceramic capacitors that have a DC bias effect. In this case, the capacitance of the such capacitors may be variable and forms a tuning capacitance to ensure that the AC energy provided by the wall box unit 16 provides resonance between the base pad 18 and the vehicle pad 20 during vehicle charging. It is recognized that any one or more components as illustrated in FIG. 1 to form the wall box unit 16 (or the power generating device) may be separately implemented in the base pad 18. Thus, it is recognized that the base pad 18 may also be defined to comprise a power generating device.

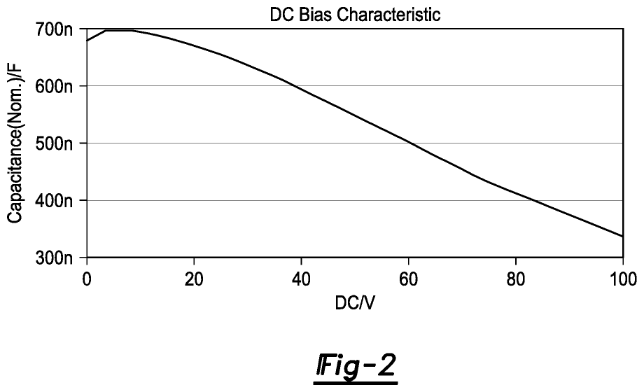

FIG. 2 generally illustrates a plot of DC voltage as applied to a tuning capacitor of the tuning capacitor network 52 (e.g., see x-axis) and the corresponding capacitance (see y-axis) for the tuning capacitor network 52. As shown, as the DC voltage increases, the capacitance decreases and vice versa. As an example, FIG. 2 generally illustrates that the tuning capacitor of the tuning capacitor network 52 changes from 700 nF to 350 nF under the presence or influence of a DC bias voltage from 20 to 100V. As the DC voltage across the tuning capacitor changes (or increases), the capacitance of the tuning capacitor drops. In one example, the tuning capacitor may change from 700 nF to 350 nF under the presence of a DC bias voltage from 20 to 100 volts.

Referring back to FIG. 1, the base pad 18 further includes a first controller 72. The controller 72 measures the alignment of the base coils 70 to vehicle coils 92 and provides status of the alignment back to the supervisor controller 54 and HV controller 56. In addition, the first controller 72 performs safety check functions including a base coil temperature measurement. In this case, the supervisor controller 54 generally communicates with the first controller 72. The supervisor controller 54 may make a determination if conditions are correct to be able to provide a charge to the vehicle 14.

The vehicle pad 20 generally includes resonant components 90, vehicle coils 92, and an alignment antenna 94. The vehicle coils 92 receive the AC energy from the base coils 70 of the base pad 18. The resonant components 90 receive the AC energy from the vehicle coils 92. The alignment antenna 94 transmits a signal to the first controller 72 that can be used to calculate the alignment of the base coils 70 to the vehicle coils 92. As noted above, the vehicle control unit 22 generally includes the communication network 80 and the transceiver 82 for providing the current charging state, desired voltage output from the base pad 18, and a duration in time to provide the desired voltage output from the wall box unit 16 for purposes of charging the battery 24. The vehicle control unit 22 also includes a rectifier circuit 101, a controller 102, and a low voltage (LV) controller 105. The rectifier circuit 101 is configured to convert the AC energy as received at the vehicle pad 20 into DC energy (e.g., as a high voltage >200 Volts) for storage on the battery 24. The LV controller 105 is configured to control the manner in which the communication network 80 communicates with the communication network 60 of the wall box unit 16.

FIGS. 3A-3B depict a more detailed view of the wall box unit 16 in accordance to one embodiment. The supervisor controller 54 includes a surge protection and current sensing block 100, a WiFi controller 102, a supervisor microprocessor 103, a first isolated communication link 104, and a second isolated communication link 106. It is recognized that the WiFi controller 102 may include the vehicle communication network 60 as noted above in connection with FIG. 1. The first isolated communication link 104 may enable a dedicated bi-directional communication interface with the PFC circuit 64. The second communication link 106 may enable a dedicated bi-directional communication interface with the HV controller 56. The surge protection and current sensing block 100 may sense current on the incoming AC signal (e.g., AC signal coming for a building, structure, grid, etc.) to ensure that the current on the incoming AC signal does not exceed a predetermined current threshold. The supervisor microprocessor 103 may control all functions performed by the supervisor controller 54. The supervisor microprocessor 103 interfaces with the sensing block 100 and may disable the controller 54 when the current in the coming AC signal exceeds the predetermined threshold. The supervisor microprocessor 103 may also transmit/receive data to and from the PFC circuit 64 and the HV controller 56. The transmitted/received data may correspond to information transmitted from the vehicle 14 to the wall box unit 16. The WiFi controller 102 and the transceiver 63 enable wireless transmission and reception of data to and from the vehicle 14.

As noted above, the PFC circuit 64 may increase a power factor of the filtered incoming AC signal to generate the increased incoming AC signal. The PFC controller 110 may also convert energy from the AC input voltage to a DC output voltage for storage on the bulk capacitors (or capacitor bank) 114a, 114b. The PFC circuit 64 includes the EMC filter 62, a PFC controller 110, and a voltage sense circuit 112. The PFC controller 110 facilitates bi-direction communication with the supervisor controller 54. The PFC circuit 64 includes a plurality of resistors (e.g., R1 and R2) and a bank of capacitors 114a, 114b that are in parallel with one another. The voltage sense circuit 112 may measure the voltage on the bulk capacitors 114a, 114b and provide information indicative of the measured voltage on the bulk capacitors 114a, 114b to the PFC controller 110 to regulate the voltage on the bulk capacitors 114. When the desired voltage on the bulk capacitors 114a, 114b is greater than a predetermined voltage of, for example, about 450V, it is desired to split the capacitor bank into a parallel-series bank of capacitors due to voltage limitations of bulk capacitors 114. When capacitors are placed in series, additional resistors may be placed in parallel to the bulk capacitor 114 provide voltage balancing. The additional resistors may balance the voltage on the capacitor banks 114 such that approximately ½ of the total bulk voltage may be placed on each capacitor. The PFC circuit 64 includes a plurality of resistors (e.g., R1 and R2) and a bank of capacitors 114 that are in parallel with one another.

The resonant component circuitry 50 includes the tuning capacitor network 52, a first inverter portion 120, and a second inverter portion 140. The first inverter portion 120 includes a first transformer 122a that is coupled to the tuning capacitor network 52. Likewise, the second inverter portion 140 includes a second transformer 122b that is coupled to the tuning capacitor network 52. While FIG. 2 illustrates that the tuning capacitor network 52 is positioned within the wall box unit 16, it is recognized that the tuning capacitor network 52 may be positioned elsewhere within the network 12. The first inverter portion 120 and the second inverter portion 140 may operate independently of one another. It is recognized that only a single inverter portion may be utilized, and that the presence of additional inverters provide additional current output to meet vehicle level charging requirements.

Each of the first inverter portion 120 and the second inverter portion 140 includes a plurality of temperature sensors 121a-121n, a DC blocking capacitor 124, a plurality of gate drivers 126a-126n, a plurality of switching devices 128a-128n, and a plurality of current sensors 130a-130n. In general, each of the gate drivers 126a-126n drive the switching devices 128a, 128n, respectively to invert the DC energy back into AC energy for delivery to the base pad 18 via a connection 150. The HV controller 56 may control the gate drivers 126a-126n such that the gate drivers 126a-126n selectively switch the switching devices 128a-128n accordingly. In particular, the HV controller 56 controls the gate drivers 126a-126 to control the switching duty cycle of the switching devices 128a-128n based on a requested voltage and duration as provided in a message from the vehicle 14 to the wall box unit 16. The current sensors 130a-130n monitor an equivalent current (or power) generated by the first and second inverter portions 120, 140 to provide the AC energy to the base pad 18 and subsequently to the vehicle 14 to ensure that the AC energy output that is being generated coincides with the requested voltage (or power) amount from the vehicle 14. In particular, the current sensors 130a-130n provide measurements that provide phase information and magnitude information. The HV controller 56 utilizes the measurements provided by the current sensor 130a-130n to determine the corresponding output power of the wall box unit 16 and to compare the output power to the requested power amount from the vehicle 14. For example, the current measurements include both phase and magnitude. These measurements provide a specific operating mode of the inverter 120. In general, various modes of operation of the inverter 120 may include capacitive, resistive or inductive. The phase relationship between the current and the control of the inverter 120 can be used to measure the mode of operation. Various preferred modes of operation may include resistive and inductive. The magnitude of the current signal provides an indication of the power to be provided by the inverter 120.

The wall box unit 16 further includes an additional current sensor 151 and a DC power supply 152. The DC power supply 152 provides a DC based voltage to the tuning capacitor network 52 to influence the amount of capacitance that is provided on the AC energy to the base pad 18. As noted above, the tuning capacitor network 52 includes capacitors whose capacitance varies based on the amount of DC voltage that is provided thereto. The current sensor 151 measures an amplitude of the AC current in the output to the base pad 18 from the wall box unit 16 in addition to a frequency and the phase of the AC current. The current sensor 151 provides this information to the HV controller 56. In general, the AC current provides a measure of the total energy in the magnetic field of the ground pad 18. The HV controller 56 uses the power provided by the inverter 120 and the energy in the magnetic field to determine an electric to magnetic efficiency. With closed loop feedback from the vehicle control unit 22, the HV Controller 56 can determine power magnetic to magnetic efficiency and magnetic to electric efficiency. Using control of the inverter frequency, the HV controller 56 starts with an initial selection for the tuning capacitor 52 based on an alignment and operating power. The HV controller 56 then executes a search algorithm to fine tune a value for the tuning capacitor 52. For example, the HV controller 56 may calculate the magnetic to magnetic efficiency for (1) a current tuning point; (2) the tuning with a slightly higher capacitance; and (3) the tuning point with a slightly lower capacitance. The HV controller 56 may then select the capacitance that resulted in the best magnetic to magnetic efficiency. The magnetic to magnetic efficiency may be the highest when the resonant frequency of the ground pad 18 is adjusted to be the same as the resonant frequency of the vehicle pad 70. The HV controller 56 may recursively apply the above process during the power transfer process. In a similar way, the HV controller 56 may be adjusting the control frequency of the inverter 120 to achieve a high electric to magnetic efficiency.

As noted above, the resonant frequency may be used to determine the amount of capacitance that is needed to be added to the AC energy output. Thus, in the event additional capacitance is required, the supervisor controller 54 and/or the HV controller 56 may then control the DC power supply 152 to reduce the amount of voltage that is applied to the tuning capacitor network 52 to provide additional capacitance to the AC energy that is output from the wall box unit 16. This aspect assists in creating resonance (i.e., tuning) between the base pad 18 to the vehicle pad 20 to account for height (or length) variations between the vehicle pad 20 and the base pad 18. Alternatively, in the event a reduction in capacitance is required from the tuning capacitor network 52, the supervisor controller 54 and/or the HV controller 56 may then control the DC power supply 152 to increase the amount of voltage that is applied to the tuning capacitor network 52 to provide less capacitance to the AC energy that is output from the wall box unit 16. This type of variable tuning assists in creating resonance between the base pad 18 to the vehicle pad 20 account for height (or length) variations between the vehicle pad 20 and the base pad 18 and also accounts for part to part variation with respect to the electronics in the network 52.

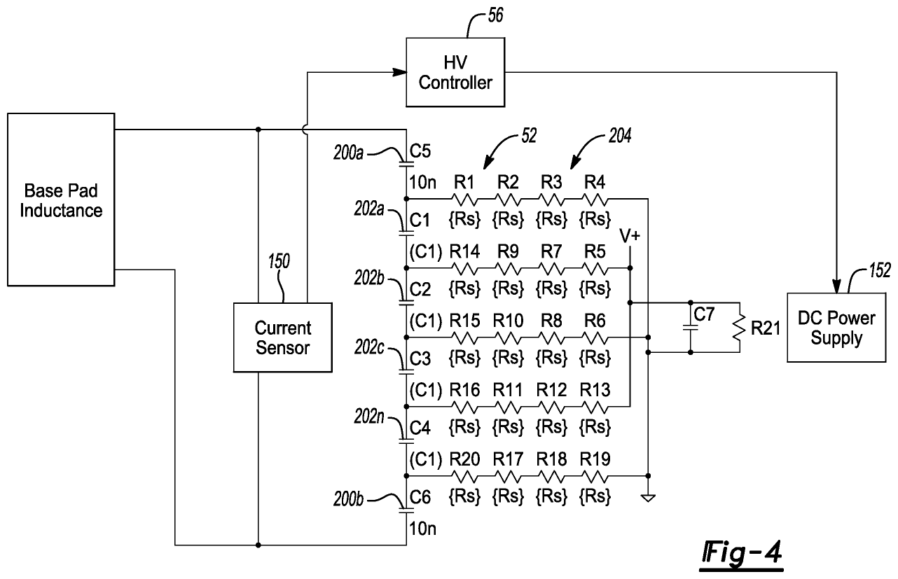

FIG. 4 generally depicts a more detailed implementation of the tuning capacitor network 52 in accordance to one embodiment. In particular, the tuning capacitor network 52 generally includes a first set of capacitors 200a and 200b, a second set of capacitors 202a-202n, and a resistor bank generally illustrated as 204. It is recognized that the number of capacitors 200 and 202 may vary based on the requirements of a particular implementation. While not illustrated, additional capacitors may be coupled in series with each of the capacitors 200a and 200b to form a network of capacitors 200 and 202 that are in parallel and series with one another. In one example, the capacitors 200a, 200b and 202a-202n may provide 90 uH to achieve total resonance with the base pad 18. Likewise, the number of resistors in the bank 204 may also vary based on the requirements of a particular implementation. As shown, the DC power supply 152 is coupled with the resistor bank 204 for providing the DC voltage thereto. A capacitance of the first set of capacitors 200a and 200b is generally static and may not change due to the presence of the DC voltage. The capacitance of the second set of capacitors 202a and 202n may vary based on the amount of DC voltage that is applied by the DC power supply 152. As also shown, the resistors that form the bank 204 are arranged in a series of rows to provide isolated DC voltage from the DC power supply 152 to the second set of capacitors 202a-202n. Thus, the DC voltage is isolated from the AC current that flows through the first set of capacitors 200a and 200b and through the second set of capacitors 202a-202n. The resistor bank 204 generally serves as a low pass filter to isolate the DC power supply 152 from, for example, an 85 kHz AC frequency.

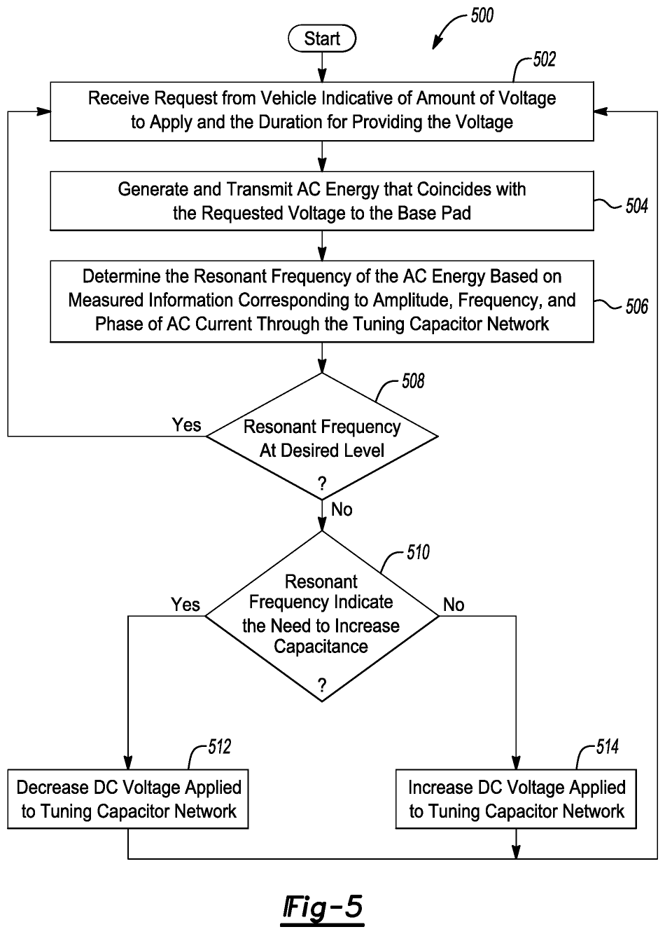

FIG. 5 generally depicts one example of a method 500 for performing a variable wireless tuning network in accordance to one embodiment. I have provided a little more detail on the search algorithm the we use above.

In operation 502, the wall box unit 16 receives a request from the vehicle 14 that is indicative of the amount of voltage (or power) that is required to be provided by the base pad 18 to the vehicle pad 20 to charge the battery 24 of the vehicle 14. The request also indicates a duration which indicates a time period for providing the requested power to the vehicle 14.

In operation 504, the wall box unit 16 generates and transmits AC energy (or energy signal) corresponding to the requested power amount to the base pad 18.

In operation 506, the wall box unit 16 determines the resonant frequency of the AC energy as output therefrom. As noted above, the current sensor 151 measures an amplitude, frequency, and phase of AC current that flows through the tuning capacitor network 52 and transmit such information to the supervisor controller 54 and/or the HV controller 56. In turn, the supervisor controller 54 and/or the HV controller 56 determines the resonant frequency of the AC energy. As noted above, The current sensor 151 measures an amplitude of the AC current in the output to the base pad 18 from the wall box unit 16 in addition to a frequency and the phase of the AC current. The current sensor 151 provides this information to the HV controller 56. In general, the AC current provides a measure of the total energy in the magnetic field of the ground pad 18. The HV controller 56 uses the power provided by the inverter 120 and the energy in the magnetic field to determine an electric to magnetic efficiency. With closed loop feedback from the vehicle control unit 22, the HV controller 56 can determine power magnetic to magnetic efficiency and magnetic to electric efficiency. Using control of the inverter frequency, the HV controller 56 starts with an initial selection for the tuning capacitor 52 based on an alignment and operating power. The HV controller 56 then executes a search algorithm to fine tune a value for the tuning capacitor 52. For example, the HV controller 56 may calculate the magnetic to magnetic efficiency for (1) a current tuning point; (2) the tuning with a slightly higher capacitance; and (3) the tuning point with a slightly lower capacitance. The HV controller 56 may then select the capacitance that resulted in the best magnetic to magnetic efficiency. The magnetic to magnetic efficiency may be the highest when the resonant frequency of the ground pad 18 is adjusted to be the same as the resonant frequency of the vehicle pad 70. The HV controller 56 may recursively apply the above process during the power transfer process. In a similar way, the HV controller 56 may be adjusting the control frequency of the inverter 120 to achieve a high electric to magnetic efficiency.

In operation 508, the wall box unit 16 compares the resonant frequency to a predetermined resonant frequency amount to determine if the determined resonant frequency is adequate. If the resonant frequency is similar to the predetermined resonant frequency amount, then the method 500 moves back to operation 502. If not, then the method 500 moves to operation 510.

In operation 510, the wall box unit 16 determines whether the resonant frequency is less than the predetermined resonant frequency amount. If this condition is true, then there is a need to increase the capacitance of the AC energy as output from the wall box unit 16. In this case, the method 500 moves to operation 512. If this condition is false, then there is a need to decrease the capacitance of the AC energy as output from the wall box unit 16. In this case, the method 500 moves to operation 514.

In operation 512, the DC power supply 152 decreases the amount of voltage that is applied to the tuning capacitor network 52 to increase the capacitance of the AC energy as provided from the wall box unit 16 to the base pad 18.

In operation 514, the DC power supply 152 decreases the amount of voltage that is applied to the tuning capacitor network 52 to increase the capacitance of the AC energy as provided from the wall box unit 16 to the base pad 18.

While exemplary embodiments are described above, it is not intended that these embodiments describe all possible forms of the invention. Rather, the words used in the specification are words of description rather than limitation, and it is understood that various changes may be made without departing from the spirit and scope of the invention. Additionally, the features of various implementing embodiments may be combined to form further embodiments of the invention.

What is claimed is:

1. A system for a charging a vehicle, the system comprising:
a power generating device configured to generate a first energy signal corresponding to a requested amount of voltage for one of a vehicle and a base pad during a vehicle charging operation; and
one or more controllers configured to:
receive a request indicative of the requested amount of voltage to provide to the vehicle during the vehicle charging operation;
control the power generating device to generate the first energy signal based on the request;
determine a resonant frequency of the first energy signal; and
adjust a capacitance of a tuning capacitor network based on the determined resonant frequency to compensate for a distance variation between a vehicle pad and the base pad during the vehicle charging operation.

2. The system of claim 1 further comprising a power supply configured to provide a first voltage signal to the tuning capacitor network to adjust the capacitance of the tuning capacitor network.

3. The system of claim 2, wherein the one or more controllers are configured to control the power supply to increase the first voltage signal that is applied to the tuning capacitor network to decrease the capacitance of the tuning capacitor network in the event the determined resonant frequency is above a predetermined resonant frequency amount.

4. The system of claim 3, wherein the one or more controllers are configured to control the power supply to decrease the first voltage signal that is applied to the tuning capacitor network to increase the capacitance of the tuning capacitor network in the event the determined resonant frequency is below a predetermined resonant frequency amount.

5. The system of claim 2, wherein the power supply is a direct current (DC) power supply that is configured to provide the first voltage signal to the tuning capacitor network.

6. The system of claim 2, wherein the tuning capacitor network includes a first plurality of capacitors that are connected in series with one another to receive the first voltage signal to adjust the capacitance of the tuning capacitor network.

7. The system of claim 6, wherein the tuning capacitor network includes a resistor bank to receive the first voltage signal from the power supply and a second plurality of capacitors, and wherein the resistor bank is configured to isolate the second plurality of capacitors from receiving the first voltage signal.

8. The system of claim 6, wherein each of the first plurality of capacitors are implemented as a ceramic based capacitor that exhibit a DC bias effect.

9. The system of claim 1, wherein the power generating device is an inverter.

10. A system for a charging a vehicle, the system comprising:
a vehicle pad for being positioned on a vehicle;
a base pad positioned below the vehicle pad for inductively transmitting a voltage signal to the vehicle pad during a vehicle charging operation;
a wall box unit for being positioned in a building to facilitate the vehicle charging operation between the vehicle pad and the base pad, the wall box unit including:
a power generating device configured to generate a first energy signal corresponding to a requested amount of voltage for use by the base pad to inductively transmit the voltage signal to the vehicle pad; and
one or more controllers configured to:
receive a request from the vehicle indicative of the requested amount of voltage to provide to the vehicle during the vehicle charging operation;
control the power generating device to generate the first energy signal based on the request;
determine a resonant frequency of the first energy signal; and
adjust a capacitance of a tuning capacitor network based on the determined resonant frequency to compensate for a variation in inductive coupling between the base pad and the vehicle pad during the vehicle charging operation.

11. The system of claim 10 further comprising a power supply configured to provide a first voltage signal to the tuning capacitor network to adjust the capacitance of the tuning capacitor network.

12. The system of claim 11, wherein the one or more controllers are configured to control the power supply to increase the first voltage signal that is applied to the tuning capacitor network to decrease the capacitance of the tuning capacitor network in the event the determined resonant frequency is above a predetermined resonant frequency amount.

13. The system of claim 11, wherein the one or more controllers are configured to control the power supply to decrease the first voltage signal that is applied to the tuning capacitor network to increase the capacitance of the tuning capacitor network in the event the determined resonant frequency is below a predetermined resonant frequency amount.

14. The system of claim 11, wherein the power supply is a direct current (DC) power supply that is configured to provide the first voltage signal to the tuning capacitor network.

15. The system of claim 11, wherein the tuning capacitor network includes a first plurality of capacitors that are connected in series with one another to receive the first voltage signal to adjust the capacitance of the tuning capacitor network.

16. The system of claim 15, wherein the tuning capacitor network includes a resistor bank to receive the first voltage signal from the power supply and a second plurality of capacitors, and wherein the resistor bank is configured to isolate the second plurality of capacitors from receiving the first voltage signal.

17. The system of claim 16, wherein each of the first plurality of capacitors are implemented as a ceramic based capacitor that exhibit a DC bias effect.

18. The system of claim 12, wherein the power generating device is an inverter.

19. A method for a charging a vehicle, the method comprising:
generating, via a power generating device, a first energy signal corresponding to a requested amount of voltage for one of a vehicle and a base pad during a vehicle charging operation;
receiving a request from the vehicle indicative of the requested amount of voltage to provide to the vehicle during the vehicle charging operation;
controlling the power generating device to generate the first energy signal based on the request;
determining a resonant frequency of the first energy signal; and
adjusting a capacitance of a tuning capacitor network based on the determined resonant frequency to compensate for a variation between the vehicle and the base pad during the vehicle charging operation.

20. The method of claim 19 further comprising providing a first voltage signal, via a direct current (DC) voltage source to the tuning capacitor network to adjust the capacitance of the tuning capacitor network.
